(19) United States
(12) Patent Application Publication
(10) Pub. No.: US 2026/0271242 A1
(43) Pub. Date: Sep. 10, 2026

(54) ELECTRONIC DEVICE

(71) Applicants: INVENTEC (PUDONG) TECHNOLOGY CORPORATION, Shanghai (CN); INVENTEC CORPORATION, Taipei City (TW)

(72) Inventors: Guoping WU, Shanghai (CN); Lian-Fei ZHANG, Shanghai (CN)

(73) Assignees: INVENTEC (PUDONG) TECHNOLOGY CORPORATION, Shanghai (CN); INVENTEC CORPORATION, Taipei City (TW)

(21) Appl. No.: 19/215,476

(22) Filed: May 22, 2025

(30) Foreign Application Priority Data
Mar. 7, 2025 (CN) 202510268113.8

(51) Int. Cl. H05K 7/20

(52) U.S. Cl. CPC H05K 7/20781

(57) ABSTRACT

An electronic device includes an immersion tank and a server. The server includes a casing, a circuit board, a primary heat source, a secondary heat source and a radiator. The casing is vertically disposed in the immersion tank, and has a side plate. The circuit board is disposed on the side plate, and has a front surface and a back surface facing away from each other. The back surface faces toward the side plate. The primary heat source is disposed on the back surface. The secondary heat source is disposed on the front surface. An amount of heat generated by the secondary heat source is less than an amount of heat generated by the primary heat source. The radiator is disposed on the side plate, and is thermally coupled to the primary heat source.

### CROSS-REFERENCE TO RELATED APPLICATIONS

This non-provisional application claims priority under 35 U.S.C. § 119(a) on Patent Application No(s). 202510268113.8 filed in CHINA, on Mar. 7, 2025, the entire contents of which are hereby incorporated by reference.

### BACKGROUND OF THE INVENTION

### Technical Field of the Invention

The invention relates to an electronic device, more particularly to an electronic device whose primary heat source is disposed on a back surface of a circuit board.

### Description of the Related Art

With the arrival of the big data era and the continuous development of cloud technology, the requirements for high-end servers are higher than ever, and the amount of the data needing to be processed is increasing. Accordingly, the density of heat transferring at the servers rapidly increases, and heat generated thereby also increases massively. Therefore, the issue of heat dissipation needs to be improved urgently.

Generally, the servers can be cooled by liquid cooling system. However, the cooling efficiency for electronic components with high power disposed in the servers is insufficient, thereby adversely affecting the operation of the servers. Therefore, improving the cooling efficiency for the electronic components with high power disposed in the servers is one of the key issues that researchers need to address.

### SUMMARY OF THE INVENTION

The invention provides an electronic device for improving the cooling efficiency for heat sources disposed in the server.

One embodiment of the invention provides an electronic device including an immersion tank and at least one server. The at least one server includes a casing, a circuit board, at least one primary heat source, at least one secondary heat source and at least one radiator. The casing is vertically disposed in the immersion tank, and has a side plate. The circuit board is disposed on the side plate, and has a front surface and a back surface facing away from each other. The back surface faces toward the side plate. The at least one primary heat source is disposed on the back surface. The at least one secondary heat source is disposed on the front surface. An amount of heat generated by the at least one secondary heat source is less than an amount of heat generated by the at least one primary heat source. The at least one radiator is disposed on the side plate, and is thermally coupled to the at least one primary heat source.

According to the electronic device disclosed in the above embodiment, the at least one primary heat source and the at least one secondary heat source are disposed on the back surface and the front surface of the circuit board, respectively, such that the at least one primary heat source is located away from the at least one secondary heat source to define a cooling area dedicated to the at least one primary heat source. Therefore, the at least one primary heat source can be cooled with a larger space to prevent the heat generated by the at least one primary heat source and the at least one secondary heat source from being difficult to be dissipated by accumulated in one place in a concentrate manner. Accordingly, the cooling efficiency for the at least one primary heat source disposed in the at least one server can be improved.

### BRIEF DESCRIPTION OF THE DRAWINGS

The invention will become more fully understood from the detailed description given herein below and the accompanying drawings which are given by way of illustration only and thus are not limitative of the invention and wherein:

FIG. 1 is a side view of an electronic device in accordance with an embodiment of the invention;

FIG. 2 is a perspective view of one of servers of the electronic device in FIG. 1;

FIG. 3 is an exploded view of one of the servers of the electronic device in FIG. 1;

FIG. 4 is a cross-sectional view of one of the servers of the electronic device in FIG. 1;

FIG. 5 is a perspective view of a radiator of the electronic device in FIG. 1; and

FIG. 6 is a perspective view of the radiator of the electronic device in FIG. 1 omitting a thermally conductive substrate.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

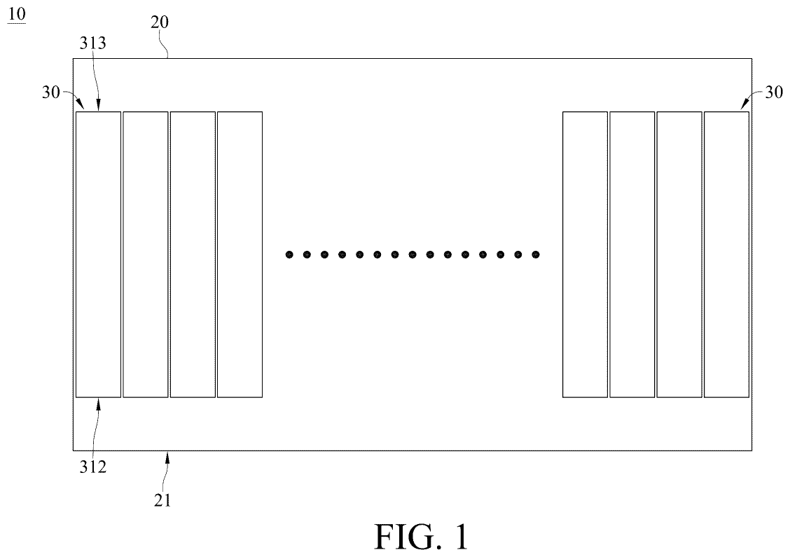

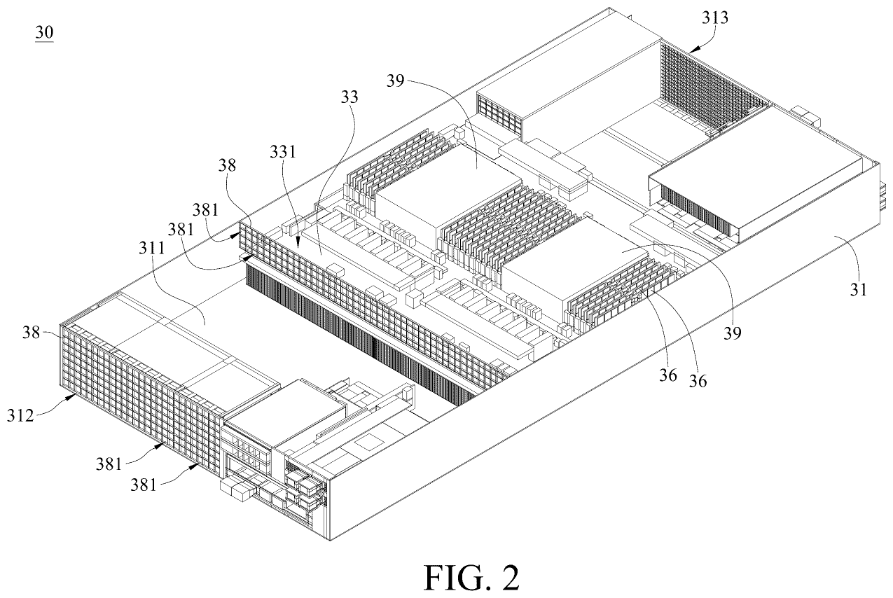

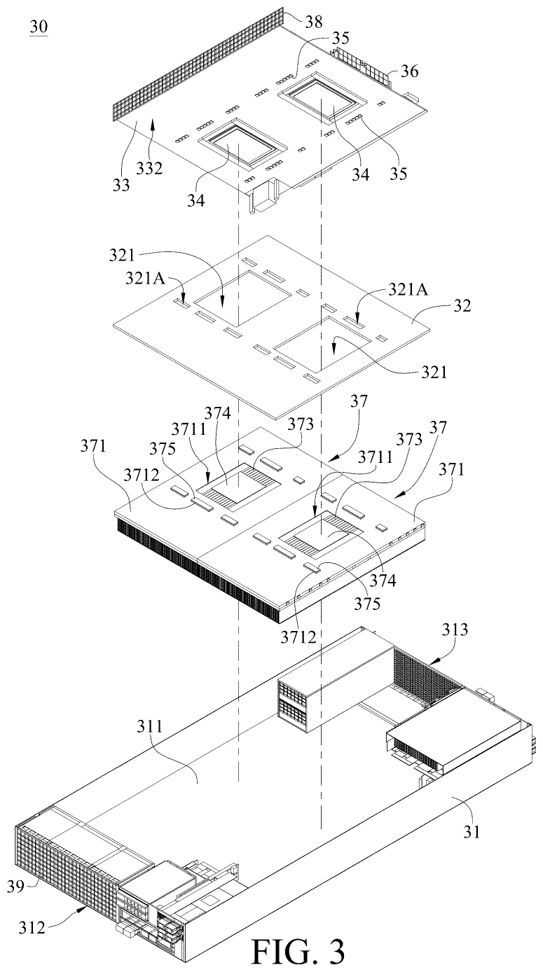

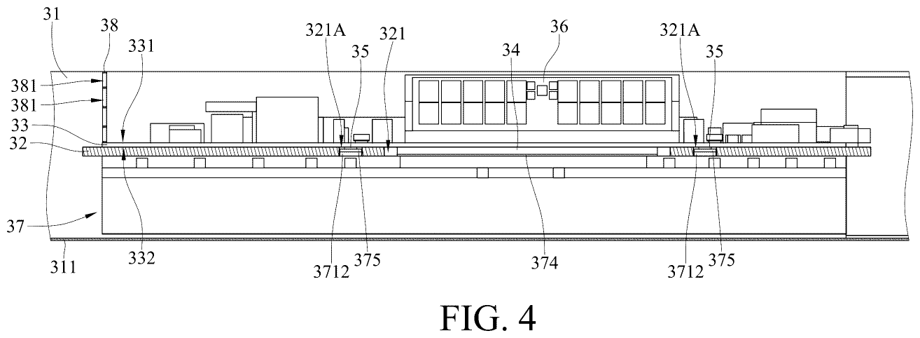

Please refer to FIG. 1 to FIG. 4, where FIG. 1 is a side view of an electronic device 10 in accordance with an embodiment of the invention, FIG. 2 is a perspective view of one of servers 30 of the electronic device 10 in FIG. 1, FIG. 3 is an exploded view of one of the servers 30 of the electronic device 10 in FIG. 1, and FIG. 4 is a cross-sectional view of one of the servers 30 of the electronic device 10 in FIG. 1.

In this embodiment, the electronic device 10 includes an immersion tank 20 and a plurality of servers 30, and the servers 30 is cooled by, for example, a single-phase immersion liquid cooling system. The immersion tank 20 is configured to accommodate a cooling fluid (not shown). The cooling fluid is, for example, water or coolant. The servers 30 are arranged side by side, and each of the servers 30 includes a casing 31, a tray 32, a circuit board 33, a plurality of primary heat sources 34, a plurality of vice heat sources 35, a plurality of secondary heat sources 36 and a plurality of radiators 37. The casing 31 is vertically disposed in the immersion tank 20, and is immersed in the cooling fluid. The casing 31 has a side plate 311. The tray 32 is disposed in the casing 31, and supports the circuit board 33. The circuit board 33 has a front surface 331 and a back surface 332 facing away from each other. The back surface 332 faces toward the side plate 311.

The primary heat sources 34 are, for example, CPU chips. The vice heat sources 35 are, for example, electronic components such as VR MOS chips. The primary heat sources 34 and the vice heat sources 35 are disposed on the back surface 332. The secondary heat sources 36 are, for example, electronic components with low power such as DIMMs and capacitors and inductors that are high, and are disposed on the front surface 331. That is, the primary heat sources 34, the vice heat sources 35 and the secondary heat sources 36 are disposed on opposite sides of the circuit board 33, respectively, which means that the primary heat sources 34, the vice heat sources 35 and the secondary heat sources 36 are disposed in layers. The primary heat sources 34 and the vice heat sources 35 are disposed on a bottom side (lower layer) of the circuit board 33. An amount of heat generated by the secondary heat sources 36 is less than an amount of heat generated by the primary heat sources 34. The radiators 37 are disposed on the side plate 311, and are thermally coupled to the primary heat sources 34 and the vice heat sources 35, respectively.

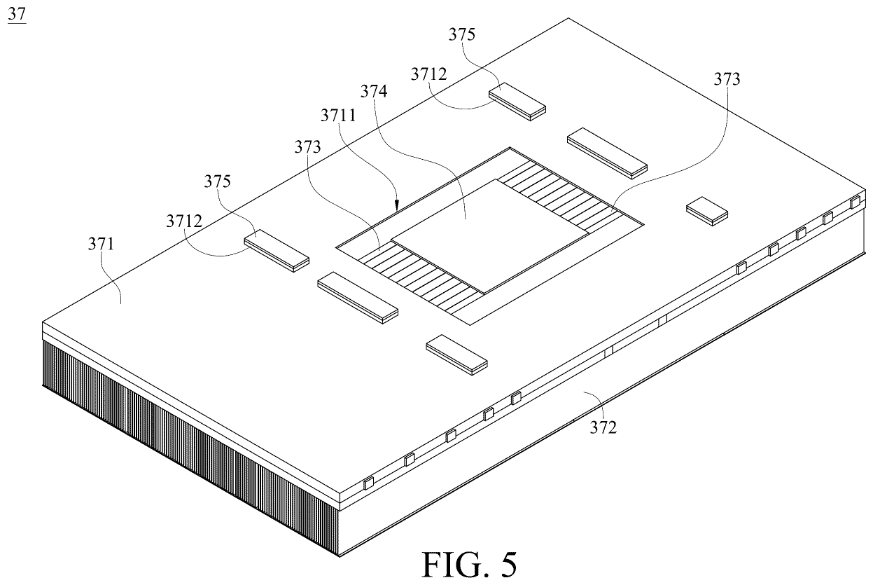

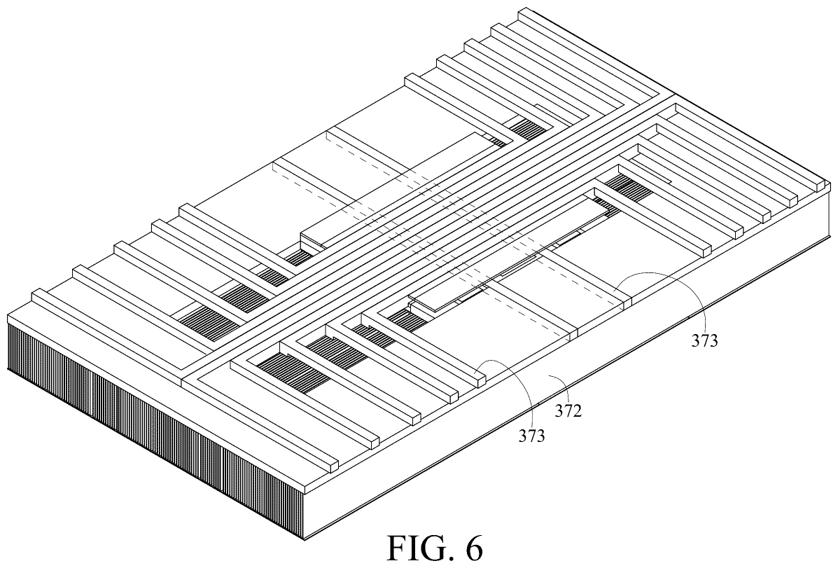

Please refer to FIG. 1 to FIG. 6, where FIG. 5 is a perspective view of the radiator 37 of the electronic device 10 in FIG. 1, and FIG. 6 is a perspective view of the radiator 37 of the electronic device 10 in FIG. 1 omitting a thermally conductive substrate 371.

In detail, each of the radiators 37 includes the thermally conductive substrate 371, a heat sink 372, a plurality of heat pipes 373, a plurality of first thermally conductive members 374 and a plurality of second thermally conductive members 375. The heat sink 372 and the heat pipes 373 are disposed on the thermally conductive substrate 371. The heat pipes 373 are disposed in, for example, layers on the thermally conductive substrate 371, but the invention is not limited thereto. The tray 32 has a plurality of first openings 321 and 321A, and the thermally conductive substrate 371 has a plurality of second openings 3711. The second openings 3711 correspond to the first openings 321, respectively. The primary heat sources 34 are disposed through the first openings 321 and the second openings 3711, and are thermally coupled to the heat pipes 373.

In this embodiment, the thermally conductive substrate 371 has a plurality of protrusions 3712. The vice heat sources 35 are disposed through the first openings 321A, and are thermally coupled to the protrusions 3712, respectively. Since a height of the vice heat sources 35 is less than a height of the primary heat sources 34, the thermal coupling between the radiators 37 and the vice heat sources 35 can be realized by the protrusions 3712.

For example, the first thermally conductive members 374 are thermal interface materials such as thermal adhesives, and are thermally coupled between the primary heat sources 34 and the heat pipes 373. For example, the second thermally conductive members 375 are thermal pads, and are thermally coupled between the vice heat sources 35 and the protrusions 3712.

The casing 31 has an inlet 312 and an outlet 313. The inlet 312 is in fluid communication with the outlet 313. The immersion tank 20 has a bottom portion 21. The inlet 312 is located closer to the bottom portion 21 than the outlet 313. The inlet 312 is configured for a cooling fluid to flow into the casing 31 so as to cool the primary heat sources 34 and the secondary heat sources 36, and the outlet 313 is configured for the cooling fluid to flow out of the casing 31.

In this embodiment, the primary heat sources 34 and the secondary heat sources 36 are disposed on the back surface 332 and the front surface 331 of the circuit board 33, respectively, such that the primary heat sources 34 are located away from the secondary heat sources 36 to define a cooling area dedicated to the primary heat sources 34. Therefore, the primary heat sources 34 can be cooled with a larger space to prevent the heat generated by the primary heat sources 34 and the secondary heat sources 36 from being difficult to be dissipated by accumulated in one place in a concentrate manner. Accordingly, the cooling efficiency for the primary heat sources 34 disposed in the servers 30 can be improved.

In this embodiment, each of the servers 30 may include two limiting plates 38. The limiting plates 38 are disposed between the inlet 312 and the secondary heat sources 36. In detail, one of the limiting plates 38 is disposed on a part of the casing 31 located close to the inlet 312, and the other limiting plate 38 is disposed on the front surface 331 of the circuit board 33. The limiting plates 38 are made of, for example, metal.

Each of the limiting plates 38 has a plurality of limiting holes 381. The limiting holes 381 are configured to limit the amount of the cooling fluid flowing through the secondary heat sources 36. In addition, a part of the cooling fluid can be redirected to flow through the primary heat sources 34 by the limiting plates 38. Upon, The primary heat sources 34 require the higher cooling capacity than the secondary heat sources 36 with the help of the limiting plates 38, additional amount of the cooling fluid are distributed to the primary heat sources 34, thereby improving the cooling capacity for the primary heat sources 34.

In this embodiment, each of the servers 30 may include a plurality of guiding members 39. The guiding members 39 are, for example, blocks, and are disposed on the front surface 331 of the circuit board 33. The guiding members 39 can block the cooling fluid and change the flowing path of the cooling fluid so as to guide the cooling fluid to flow toward the secondary heat sources 36 in a concentrated manner.

In this embodiment, each of the servers 30 includes the tray 32, and the tray 32 supports the circuit board 33, but the invention is not limited thereto. In other embodiments, each of the servers may not include the tray, and the circuit board is disposed on, for example, the side plate.

In this embodiment, there are multiple primary heat sources 34, multiple vice heat sources 35, multiple secondary heat sources 36, multiple radiators 37, multiple first openings 321 and 321A and multiple second openings 3711, but the invention is not limited thereto. In other embodiments, there may be one primary heat source, one vice heat source, one secondary heat source, one radiator merely, one first opening merely and one second opening merely.

In this embodiment, each of the radiators 37 includes multiple heat pipes 373, but the invention is not limited thereto. In other embodiments, each of the radiators may include one heat pipe merely.

In this embodiment, each of the radiators 37 includes the heat pipes 373, but the invention is not limited thereto. In other embodiments, the heat pipes may be replaced with vapor chambers.

In this embodiment, the thermally conductive substrate 371 has multiple protrusions 3712, but the invention is not limited thereto. In other embodiments, the thermally conductive substrate may have one protrusion merely, as long as the quantity of the protrusions corresponds to the quantity of the vice heat sources.

In this embodiment, each of the servers 30 includes multiple first thermally conductive members 374 and multiple second thermally conductive members 375, but the invention is not limited thereto. In other embodiments, each of the servers may include one first thermally conductive member and one second thermally conductive member merely.

In this embodiment, each of the servers 30 includes two limiting plates 38. One of the limiting plates 38 is disposed on the part of the casing 31 located close to the inlet 312, and the other limiting plate 38 is disposed on the front surface 331 of the circuit board 33, but th e invention is not limited thereto. In other embodiments, each of the servers may include one limiting plate merely, and the limiting plate may be disposed on the part of the casing located close to the inlet or the front surface of the circuit board, or each of the servers may include more than two limiting plates.

According to the electronic device disclosed in the above embodiment, the primary heat sources and the secondary heat sources are disposed on the back surface and the front surface of the circuit board, respectively, such that the primary heat sources are located away from the secondary heat sources to define a cooling area dedicated to the primary heat sources. Therefore, the primary heat sources can be cooled with a larger space to prevent the heat generated by the primary heat sources and the secondary heat sources from being difficult to be dissipated by accumulated in one place in a concentrate manner. Accordingly, the cooling efficiency for the primary heat sources disposed in the servers can be improved.

It will be apparent to those skilled in the art that various modifications and variations can be made to the invention. It is intended that the specification and examples be considered as exemplary embodiments only, with the scope of the invention being indicated by the following claims.

What is claimed is:

1. An electronic device, comprising:
an immersion tank; and
at least one server, comprising:
a casing, vertically disposed in the immersion tank and having a side plate;
a circuit board, disposed on the side plate and having a front surface and a back surface facing away from each other, wherein the back surface faces toward the side plate;
at least one primary heat source, disposed on the back surface;
at least one secondary heat source, disposed on the front surface, wherein an amount of heat generated by the at least one secondary heat source is less than an amount of heat generated by the at least one primary heat source; and
at least one radiator, disposed on the side plate and thermally coupled to the at least one primary heat source.

2. The electronic device according to claim 1, wherein the at least one server further comprises a tray, the tray is disposed in the casing, and supports the circuit board.

3. The electronic device according to claim 2, wherein the tray has at least one first opening, and the at least one primary heat source is disposed through the at least one first opening.

4. The electronic device according to claim 3, wherein the at least one radiator comprises a thermally conductive substrate, a heat sink and at least one heat pipe, the heat sink and the at least one heat pipe are disposed on the thermally conductive substrate, the thermally conductive substrate has a second opening, the second opening corresponds to the at least one first opening, the at least one primary heat source is disposed through the second opening, and is thermally coupled to the at least one heat pipe.

5. The electronic device according to claim 4, wherein the at least one server further comprises at least one vice heat source, wherein the at least one vice heat source is disposed on the back surface, the thermally conductive substrate has at least one protrusion, and the at least one vice heat source is thermally coupled to the at least one protrusion.

6. The electronic device according to claim 5, wherein the at least one radiator further comprises at least one first thermally conductive member and at least one second thermally conductive member, the at least one first thermally conductive member is thermally coupled between the at least one primary heat source and the at least one heat pipe, and the at least one second thermally conductive member is thermally coupled between the at least one vice heat source and the at least one protrusion.

7. The electronic device according to claim 1, wherein the casing further has an inlet and an outlet, the inlet is configured for a cooling fluid to flow into the casing, and the outlet is configured for the cooling fluid to flow out of the casing.

8. The electronic device according to claim 7, wherein the at least one server further comprises at least one limiting plate, wherein the at least one limiting plate is disposed between the inlet and the at least one secondary heat source, and has a plurality of limiting holes, and the plurality of limiting holes are configured to limit the amount of the cooling fluid flowing through the at least one secondary heat source.

9. The electronic device according to claim 7, wherein the immersion tank has a bottom portion, and the inlet is located closer to the bottom portion than the outlet.

10. The electronic device according to claim 1, wherein the at least one server further comprises at least one guiding member, the at least one guiding member is disposed on the front surface to guide a cooling fluid to flow toward the at least one secondary heat source.
